(19) United States
(12) Patent Application Publication
(10) Pub. No.: US 2016/0141830 A1
(43) Pub. Date: May 19, 2016

(54) TO-TYPE OPTICAL ELEMENT PACKAGE FOR HIGH-SPEED COMMUNICATION

(71) Applicant: PHOVEL.CO.LTD., Yuseong-gu, Daejeon (KR)

(72) Inventor: Jeong-Soo KIM, Gongju-si, Chungcheongnam-do (KR)

(21) Appl. No.: 14/899,623

(22) PCT Filed: May 12, 2014
(86) PCT No.: PCT/KR2014/004199

§ 371 Date: Dec. 18, 2015

(30) Foreign Application Priority Data
Jun. 19, 2013 (KR) 10-2013-0070578
Sep. 16, 2013 (KR) 10-2013-0111169

(51) Int. Cl. H01S 5/022; H01S 5/024

(52) U.S. Cl. CPC H01S 5/02212; H01S 5/02415; H01S 5/02236

(57) ABSTRACT

A TO-type optical element package for high-speed communication which is used for an optical module for high-speed communication of at least 10 gigabits per sec (Gbps) and enables thermoelectric elements to be embedded in an upper part of a stem. The TO-type optical element package for high-speed communication can transmit high-quality signals in a high-speed operation of the optical element by inserting and fixing an electrode pin (120) in a through-hole formed on a stem base (100), surrounding a lateral surface of the electrode pin (120) protruding to an upper part of the stem base (100), with a metallic instrument (400) having a through-hole so as to enable the impedance of an electrode pin (120) part, surrounded with the stem base (100), to correspond to the impedance of an electrode pin (120) part protruding to the upper part of the stem base (100).

### TECHNICAL FIELD

The present invention relates to a TO-type optical element package, particularly, a TO-type optical element package for high-speed communication that is used for an optical module for high-speed communication of at least 10 Gbps (Giga bit per sec) and can have a thermoelectric element on a stem.

### BACKGROUND ART

Recently, optical communication using light as a medium for information transmission to transmit large-size information and high-speed information communication has been popularized. Recently, it is possible to easily convert an electrical signal of 10 Gbps into laser light, using a semiconductor laser diode chip having width and length of 0.3 mm, and to easily convert an optical signal transmitted through an optical fiber into an electrical signal, using a semiconductor photodetector. Light can carry large-size information of tens of Tera bps to a long distance of hundreds of kilometers at a high speed of tens of Gbps, when an optical fiber is a medium, so it has been necessary for high-speed, large-size, and long-distance information transmission.

However, a semiconductor laser changes in wavelength in accordance with the operational temperature, so a package with a built-in thermoelectric element that can maintain the temperature of a laser diode chip at a predetermined level even if an external environment changes in temperature has been used in various fields. In the related art, for an optical module package with a built-in thermoelectric element, a butterfly package, or a mini-FLAT or mini-DIL package has been employed. However, the butterfly package and the mini-FLAT package have a defect of a very large package and a too high price. So, a TO (Transistor Outline)-type package was widely used in the related art as an inexpensive optical communication module.

FIG. 1 is a view schematically illustrating a TO-type package of the related art.

In the TO-type package illustrated in FIG. 1, electrode pins 120 made of iron, kovar, or the like are inserted and fixed in one or a plurality of holes and the metallic electrode pins 120 are fixed and sealed by glass sealing members 110. This type of package is easily to manufacture, so it is used for low-cost optical communication packages. The TO-type package has been usually used for optical communication of 2.5 Gbps.

In order to make the TO-type package for high-speed optical communication of 10 Gbps, electric signals have to be transmitted well without distortion through a signal transmission lines for transmitting electric signals among optical elements. Impedances should be matched in the electric transmission lines so that electric signals can be transmitted through the electric transmission lines without distortion of the signals.

In general, impedances are not matched well in the electrode pins 120 protruding from a stem base 100, so it has been general to minimize the lengths of the electrode pins 120 protruding out of the stem base 100 in order to operate optical elements at a high speed.

In general, the electrode pins 120 and optical elements in a TO-can package are electrically connected through signal transmission lines that are Au wires, but these signal transmission lines also have a structure in which impedances are difficult to be matched.

Accordingly, for high-speed optical communication, as in FIG. 2, a sub-mount 300 for relaying transmitted signals with a matched impedance is inserted between an electrode pin 100 and an optical element 200 disposed in a TO-can package to achieve high-speed optical communication, and FIG. 2 is a diagram illustrating electric connection between an electrode pin and an optical element in a TO-can package.

However, in FIG. 2, impedances are difficult to be matched between the signal transmission line 900 and the electrode pin 120 protruding outward without being covered by the stem base 100, so a way of minimizing the length of this portion is used.

On the other hand, recently, a TO-can package in which a thermoelectric element is disposed on a stem base 100 and various optical elements are disposed on the thermoelectric element has been widely used. FIG. 3 illustrates a typical TO-can optical element package including a thermoelectric element. A thermoelectric element 800 has a height of at least 1 mm or more, an optical element 200 disposed on the thermoelectric element 800 is positioned at least 1 mm higher than an optical element disposed directly on the stem base 100. Accordingly, it is required to increase the height of an electrode pin 120 protruding in the air to 1 mm or more in order to achieve a package in which an optical module or an optical element where the thermoelectric element 800 is attached is 1 mm or more high. The electrode pin 120 having this height has no problem with transmission of 2.5 Gbps, but causes severe distortion of signals transmitted at 10 Gbps or 5 Gbps, so it cannot transmit signals with high quality. Further, the sub-mount 300 for relaying transmitted signals includes a resistance for impedance matching in some cases, in which when a current flows through the signal transmission line 900 including the resistance, joule heat is generated. The joule heat is attached to the upper plate of the thermoelectric element 800, so the joule heat generated by the sub-mount 300 for relaying transmitted signals transfers to the upper plate of the thermoelectric element 800 and deteriorates characteristics of the thermoelectric element 800.

### PRIOR ART DOCUMENT

### Patent Document

(Patent Document 1) Korean Patent Application Publication No. 10-2012-0129137 (2012.1 1.28)

### DISCLOSURE

### Technical Problem

The present invention has been made in an effort to solve the problems in the related art and an object of the present invention is to provide a TO-type optical element package for high-speed communication that can increase the speed of a transmitted signal to allow for transmission of 10 Gbps.

Further, another object of the present invention is to provide a TO-type optical element package for high-speed communication that prevents joule heat generated by a resistance, which is included in a signal transmission line in a TO-type element package including a thermoelectric element to match impedances, from deteriorating characteristics of the thermoelectric element.

### Technical Solution

In order to achieve the object, the present invention provides a method of attaching a structure surrounding an electrode pin of a stem exposed in the air with metal having a circular hole and a method of attaching a sub-mount for relaying transmitted signals to metal having a hole surrounding an electrode pin. Herein, the sub-mount for relaying transmitted signals may include a matching resistance for impedance matching.

In a TO-type optical element package for high-speed communication according to the present invention, an electrode pin is inserted and fixed in a hole formed in a stem base and a side of the electrode pin protruding upward from the stem base is surrounded by a metal structure having a hole so that an impedance of the portion of the electrode pin surrounded by the stem base and an impedance of the portion of the electrode pin protruding upward from the stem base are matched.

Further, a sub-mount for relaying transmitted signals is attached to the metal structure to relay signals transmitted between the electrode pin and the optical element. Herein, the sub-mount for relaying transmitted signals may include a resistance for impedance matching.

Meanwhile, the sub-mount for relaying transmitted signals to relay signals transmitted between the electrode pin and the optical element may be attached to the upper portion of a thermoelectric element disposed on the stem base, and a resistance for impedance matching may be attached to the metal structure and connected to the sub-mount for relaying transmitted signals through a signal transmission line.

Further, the metal structure may be attached and electrically connected to the stem base through a solder or conductive epoxy.

Further, an insulating material may be applied to the surface of the hole of the metal structure. The metal structure may be made of aluminum and the surface of the hole may be insulated by oxidizing the metal structure (400) made of aluminum. Herein, an insulating layer may be removed at the surface of the metal structure of a portion where the metal structure and the stem base are in contact with each other.

### Advantageous Effects

A TO-type optical element package for high-speed communication according to the present invention may have a high-quality signal transmission characteristic even at a high-speed operation of an optical element by matching the impedance of an electrode pin protruding from a stem base to an impedance required in the package. Further, joule heat generated by a resistance for impedance matching that is attached to a sub-mount for relaying transmitted signals does not deteriorate the characteristic of a thermoelectric element through the stem base, so the characteristics of the thermoelectric element can be improved.

### DESCRIPTION OF DRAWINGS

FIG. 1 is a stem of a common TO-can package of the related art.

FIG. 2 is a diagram illustrating electrical connection between an electrode pin and an optical element in a common TO-can package of the related art.

FIG. 3 is a diagram illustrating electrical connection between an electrode pin and an optical element in a TO-can package having a thermoelectric element of the related art.

FIG. 4 is a view illustrating impedances according to the diameter of an electrode pin and the diameter of a stem hole in a stem made of glass having permittivity of 4 according to the present invention.

FIG. 5 is a view illustrating a process of attach a metal structure having a hole around an electrode pin so that the impedance of the portion of an electrode pin protruding over a stem base and the impedance of the portion of the electrode pin surrounded by a hole in a stem base are matched according to the present invention.

FIG. 6 is a view illustrating a state in which a sub-mount for relaying transmitted signals including a resistance for impedance matching in accordance with the present invention is attached to a metal structure.

FIG. 7 is a view illustrating a state in which a resistance for impedance matching according to the present invention is attached to a metal structure and a sub-mount for relaying transmitted signals is disposed on a thermoelectric element.

FIG. 8 is a view illustrating the structure of a single ended drive type of flexible substrate according to the present invention.

FIG. 9 is a view illustrating the structure of a differential ended drive type of flexible substrate according to the present invention.

FIG. 10 is a view illustrating arrangement of electrode pins in a stem base for an optical element for high-speed communication in a single ended drive type according to the present invention.

FIG. 11 is a view illustrating arrangement of electrode pins in a stem base for an optical element for high-speed communication in a differential ended drive type according to the present invention.

FIG. 12 is a view illustrating a process of matching impedances of electrode pins for transmitting signals, using a metal structure having a plurality of holes for matching impedances of two electrode pins protruding inside a package from a differential ended drive type of optical element to predetermined impedances, respectively, according to the present invention to predetermined impedances.

### BEST MODE

Hereinafter, preferred embodiments of the present invention are described in detail with reference to the accompanying drawings.

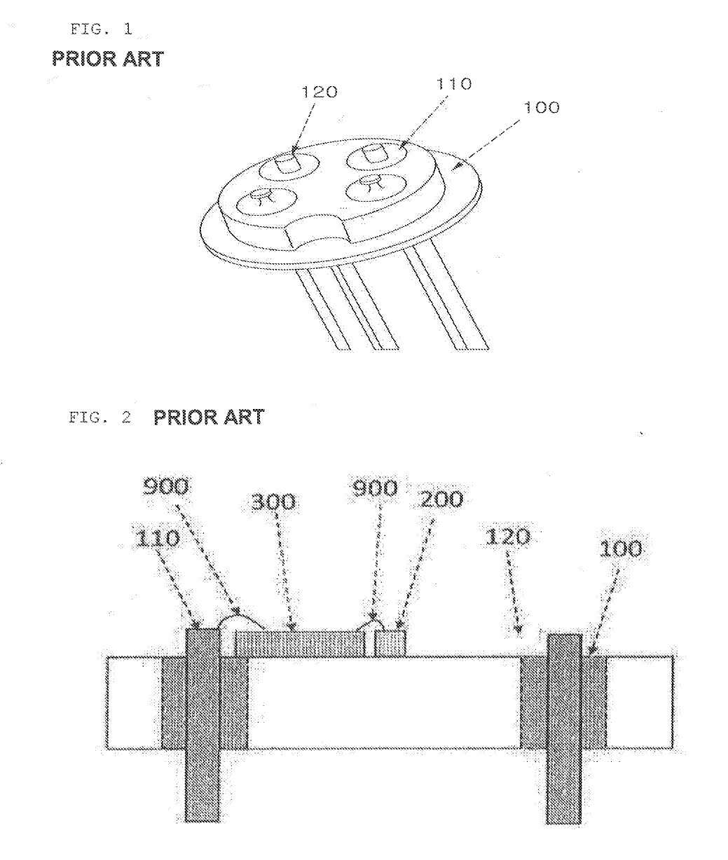

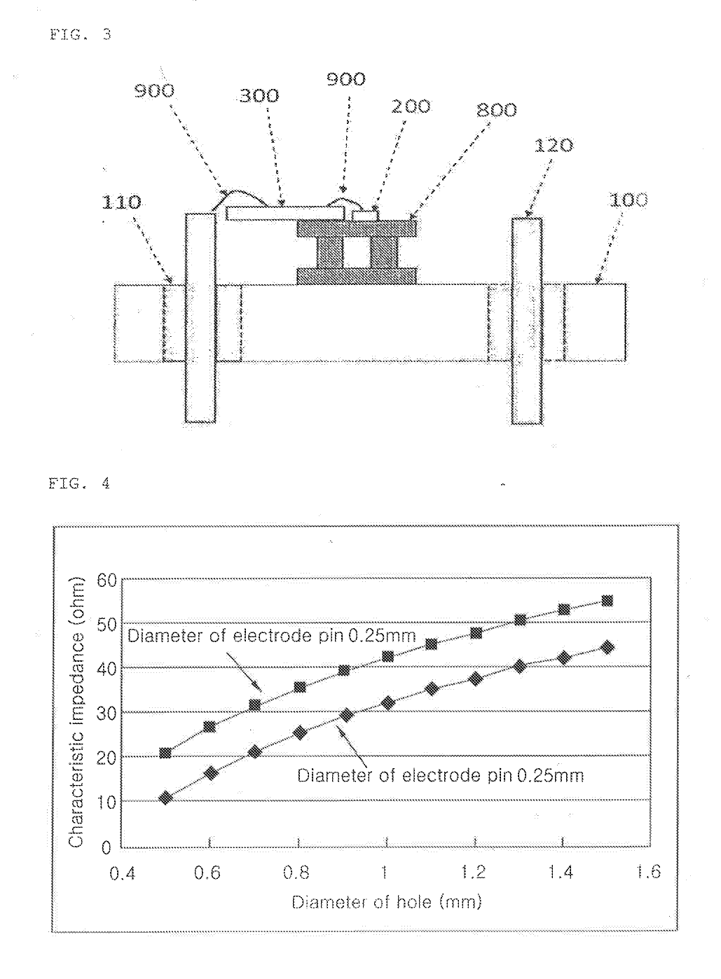

Referring to FIGS. 1 to 3, characteristic impedances or the portions of electrode pins 120 surrounded by a stem base 100 and glasses 110 can be easily adjusted by adjusting the permittivity of the glasses 110, the diameters of the electrode pins 120 and the diameters of holes through which the electrode pins 120 pass.

FIG. 4 illustrates characteristic impedances according to the diameter of a hole to diameters of 0.25 mm and 0.35 mm of electrode pins in a stem in which a stem base and an electrode pin are sealed by a glass having a permittivity of 4.

In general, optical modules are designed to have a characteristic impedance of 25 Ohm or 50 Ohm, so it is possible to match desired characteristic impedance by appropriately adjusting the diameter of the electrode pin 120 and the diameter of holes. Accordingly, the characteristic impedance of the electrode pins 120 surround by the holes in the stem base 100 can be adjusted very well by appropriately designing the diameters of the holes and electrode pins 120 in accordance with required characteristic impedance and the standards of a package.

As illustrated in FIG. 4, for characteristic impedance, the diameter of the electrode pin 120 is determined first and then the diameter of the hole in the stem base 100 is determined in accordance with a characteristic impedance relationship according to the diameter of the electrode pin 120 and the diameter of the hole.

Meanwhile, the portion of the electrode pin 120 that is not surrounded by the stem base 100, but is exposed to the air is different in impedance from the portion surrounded by the stem base 100. For example, since the cover of a TO-can package is usually made of metal, so when a metal cover having a diameter of about 4 mm functions as metal of the stem base 100, the electrode pin 120 having a diameter of 0.25 mm has a characteristic impedance of 166 Ohm and the electrode pin 120 having a diameter of 0.35 mm has a characteristic impedance of 146 Ohm. Accordingly, in the electrode pin 120 having a diameter of 0.25 mm to have a characteristic impedance of 25 Ohm, the portion surrounded by the stem base 100 has a characteristic impedance of 25 Ohm, but the portion of the electrode pin 120 protruding out of the stem base 100 has a characteristic impedance of 166 Ohm. As described above, signal reflection is generated in a period where characteristic impedance changes, so an optical element is difficult to operate at a high speed.

Meanwhile, the impedance of the electrode pin 120 exposed to the air and the impedance surrounded by the hole in the stem base 100 can be matched by surrounding the portion of the electrode pin 120 exposed upward from the stem base 100 with another metal.

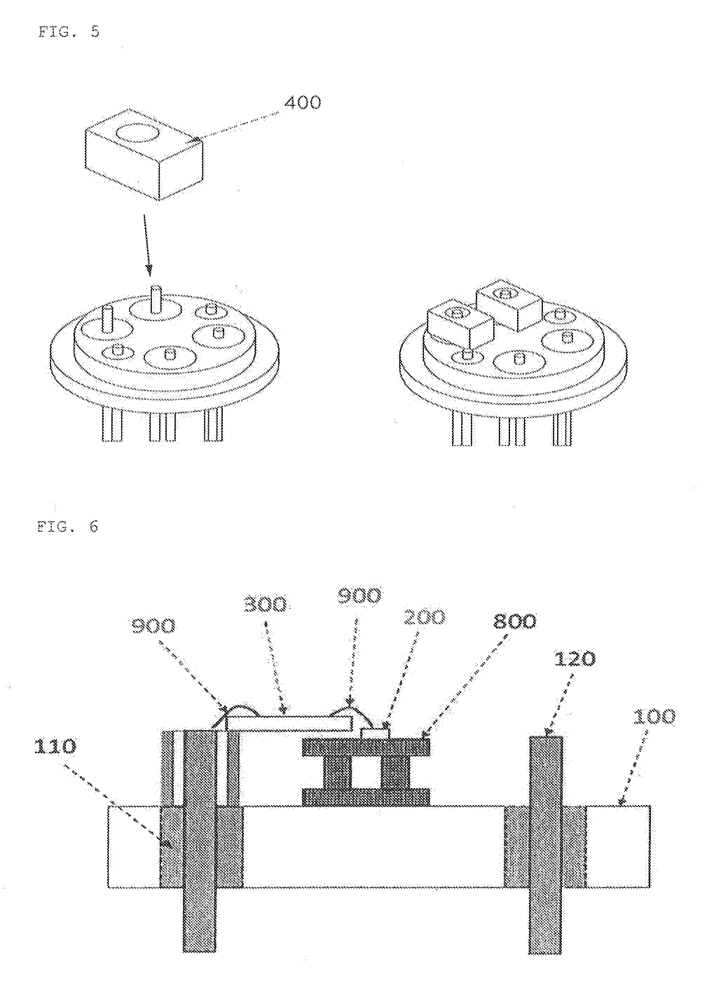

FIG. 5 is a view illustrating a process of attaching a metal structure having a hole around electrode pins exposed upward from a stem base.

As illustrated in FIG. 5, an electrode pin 120 exposed upward from the stem base 100 and a metal structure 400 are insulated by air, and as described above, the diameter of the hole in the metal structure 400 has to be 0.58 mm to achieve a characteristic impedance of 25 Ohm at the portion of the electrode pin 120, which has a diameter of 0.25 mm, protruding upward from the stem base 100. Accordingly, impedance of the electrode pin 120 exposed upward from the stem base 100 and the impedance of the portion surrounded by the stem base 100 can be matched by surrounding the portion of the electrode pin 120 exposed upward from the stem base 100 with the metal structure 400 having a hole.

In this case, the metal structure 400 and the stem base 100 need to be electrically connected, and for this purpose, a solder or conductive epoxy was used to attach the metal structure 400 to the stem base 100 in an embodiment of the present invention. Further, the material of the metal structure 400 may be any conductive metal, including aluminum, iron coated with Au, and Kovar coated with Au.

Meanwhile, when the sub-mount 300 for relaying transmitted signals includes a resistance for impedance matching, the resistance generates heat due to a current flowing through the signal transmission line 900. Accordingly, when a resistance for impedance matching is attached to the sub-mount 300 for relaying transmitted signals, the heat generated by the resistance deteriorates the characteristics of the thermoelectric elements 800. Accordingly, the sub-mount 300 for relaying transmitted signals can be allowed to relay signals between the electrode pin 120 and the optical element 200 by attaching the sub-mount 300 for relaying transmitted signals equipped with a resistance to the upper portion of the metal structure 400 attached to matching the impedance of the electrode pin 120 protruding upward from the stem base 100 such that heat generated from the sub-mount 300 for relaying transmitted signals cannot transfer to the thermoelectric element 800. FIG. 6 is a view illustrating an example in which a sub-mount for relaying transmitted signals which has a resistance for impedance matching is attached to the upper portion of a metal structure. In this case, the sub-mount 300 for relaying transmitted signals should be spaced from the upper plate of the thermoelectric element 800.

Further, a resistance for impedance matching that is attached to the sub-mount 300 for relaying transmitted signals may be disposed separately from the sub-mount 300 for relaying transmitted signals.

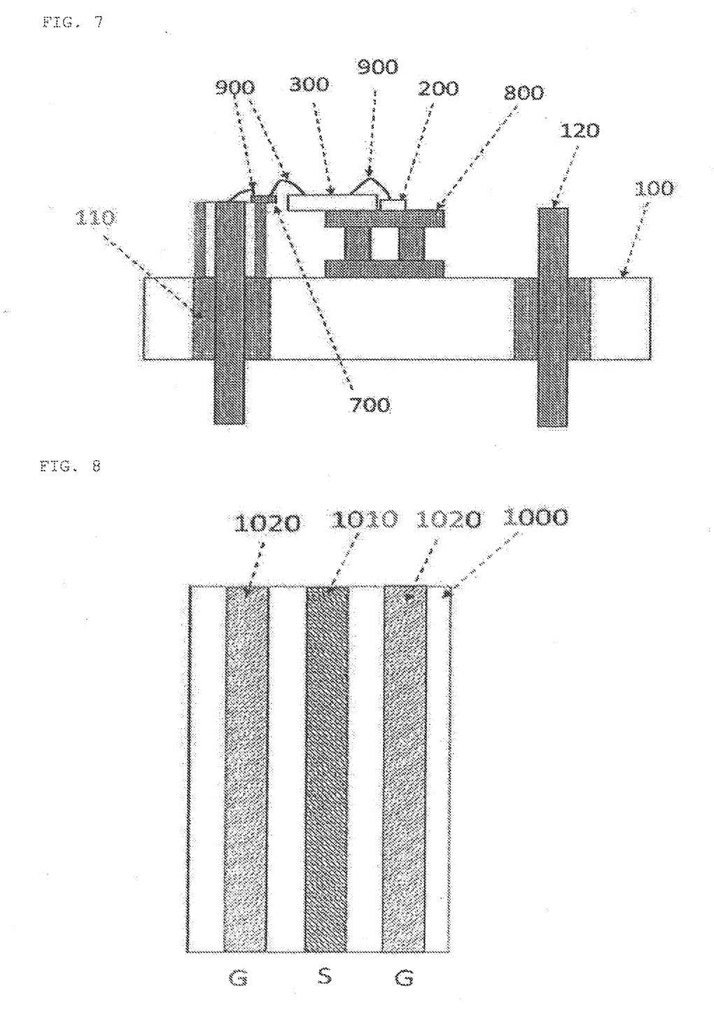

FIG. 7 is a view illustrating an example in which a resistance for impedance matching is attached to a metal structure and a sub-mount for relaying transmitted signals is attached to the upper plate of a thermoelectric element. In this structure, heat generated by a resistance 700 for impedance matching transfers to the metal structure 400, so it does not deteriorates the thermal characteristic of the thermoelectric element, and the sub-mount 300 for relaying transmitted signals effectively relay signals transmitted between the electrode pin 120 and the optical element 200, and accordingly, the optical element 200 can operate at a high speed.

Meanwhile, although it was described through an embodiment of the present invention that one electrode pin 120 protruding upward from the stem base 100 is surrounded by a metal structure 400 having one hole, the impedances of two or more electrode pins 120 may be matched respectively by metal structures 400 each having one hole and various modifications such as matching the impedances of two or more electrode pins 120 by one metal structure having two or more holes.

Further, it is also possible to coat the surface of the hole of the metal structure 400 with an insulating material to prevent a short circuit between the metal structure 400 and the electrode pin 120 exposed upward from the stem base 400. In this case, insulation is possible by applying a polymeric material to the surface of the hole of the metal structure 400 and it may be possible to make the metal structure 400 of aluminum and then insulate the surface of the hole of the metal structure 400 by oxidizing the metal structure 400. In this case, the insulating layer on the surface of the metal structure 400 at the contact portion between the metal structure 400 and the stem base 100 should be removed.

Recently, a network for the next generation optical communication such as NG-PON (Next Generation Passive Optical Network) requires a light emitting device and a photodetector that can perform communication of 10 Gbps. As described above, the main idea of the present invention can be appropriately applied to a light emitting device for high-speed communication including a thermoelectric element. At present, high-speed optical elements electrically connect a circuit board and a FPCB (Flexible PCB) and the FPCB also needs to be matched in impedance to perform high-speed communication.

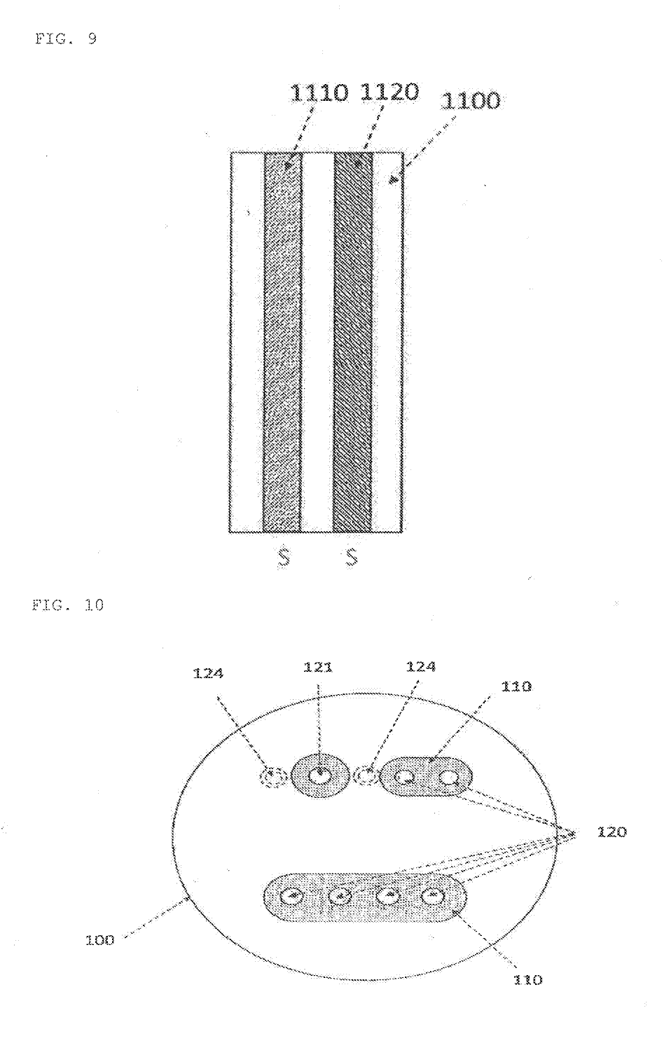

FIGS. 8 and 9 illustrate types of signal lines of an FPCB 1000 allowing for high-speed communication. FIG. 8 illustrates an FPCB 1000 in which one signal line 1010 is surrounded with two ground lines 1020 and FIG. 9 illustrates an FPCB 1000 including two signal lines 1110 and 1120 through which signals are transmitted at a high speed. The FPCB 1000 illustrated in FIG. 8 is generally used for operating a laser diode chip in a single ended drive type in a super-high-speed light emitting module and the FPCE 1000 Illustrated in FIG. 9 is generally used for operating a laser diode chip in a differential ended drive type in a super-high-speed light emitting module.

In the single ended drive type, as in FIG. 8, a TO stem ground pin connecting two ground lines 1020 of the FPCB 1000 may be disposed at the sides of signal lines of a TO stem 100.

Elements supposed to be electrically operated in a super-high-speed light emitting module including a thermoelectric element may include a thermistor 820 for measuring the temperature of thermoelectric element not illustrated in the figure, a laser diode chip 210, and a photodiode chip 220, in addition to the thermoelectric element 800. Accordingly, in a light emitting element for super-high-speed communication including these four or more elements, two independent electrode pins and a plurality of electrode pins for operating other electric elements should be included in the TO stem 100 to operate the thermoelectric element, but the TO stem 100 that has a diameter of 6 mm and is widely used at present is very small in size, so it is difficult to arranges electrode pins for operating all of these electric elements. In particular, the signal ended drive type and the differential ended drive type require specific electrode pin arrangement to transmit signals at a high speed to the laser diode chip 210 without distortion, using an FPCB.

FIG. 10 illustrates an example of arrangement of electrode pins on a stem base 100 in a light emitting device including a high-speed laser diode chip of the signal ended drive type. Ground electrode pins 124 being in direct contact with the stem base 100 at both sides of the electrode pin 121 transmitting signals at a high speed are connected to two ground lines 1020 of the FPCB 1000 of FIG. 8, and the ground line 1020 of the FPCB 1000 and the ground electrode pin 124 of the stem base 100 can be connected so that signals from the signal line 1010 of the FPCB 1000 of FIG. 8 can be smoothly connected to the electrode pin 121 of FIG. 10. In this structure, the metal structure 400 having one hole can be disposed in the TO package to match the impedance of the portion of the electrode pin exposed to the air of the electrode pins 121 for signals to a predetermined impedance.

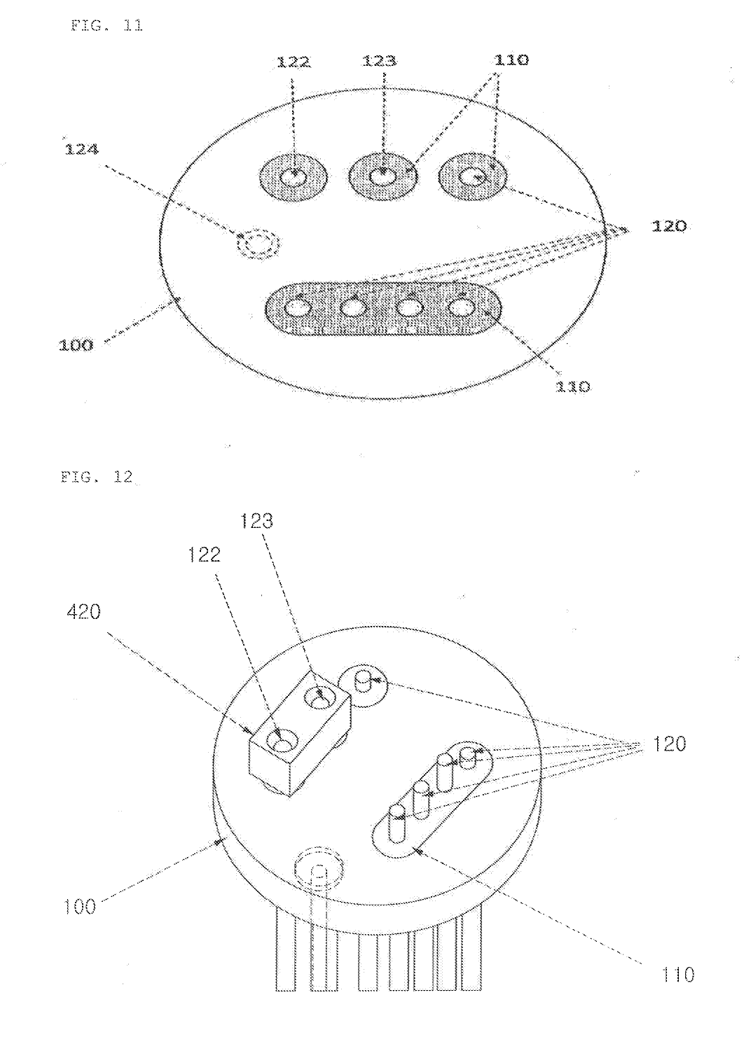

FIG. 11 illustrates an example of electrode pin arrangement on a stem base in a light emitting device using the differential ended drive type. The impedances at the portions sealed by glass in the electrode pins 122 and 123 transmitting signals at a high speed are set to predetermined impedance. In order to match the impedances of the electrode pins 122 and 123 for high-speed communication lines at the protruding in the air inside the TO-type package, a metal structure 420 having two holes may be disposed in the TO package.

FIG. 12 illustrates that the impedances of the electrode pins 122 and 1234 protruding inside a TO package are matched to a predetermined impedance, using a metal structure 420 having two holes.

In the present invention, the number and the arrangement of electrode pins have vary important technical features as themselves. That is, in single ended drive, only one electrode pin is used as an electrode pin for high-speed communication and a ground electrode is needed in this case, so eight or more electrode pins including an electrode pin for high-speed transmission are included in a TO-type stem base, in which three or four electrode pins 120 are sealed by one glass sealing member 110. A TO stem base configuration in which an electrode pin 124 for grounding, an electrode pin 121 for high-speed signal transmission, an electrode pin 124 for grounding, and one or two common electrode pins 120 are arranged in a line opposite to the three or four electrode pins 120 sealed by one glass sealing member 110 is also technically very important in the single ended drive type.

Further, in the differential ended drive type, eight or more electrode pins including an electrode pin for high-speed transmission are included, in which three or four electrode pins 120 are sealed by one glass sealing member 110. The structure in which three electrode pins 122, 123, and 120 respectively sealed by one glass sealing member 110 are disposed opposite to the three or four electrode pins and an electrode pin 124 for grounding is disposed at a side of the stem base 100 is also an important way of arranging eight or more electrode pins, considering impedance matching in a micro-TO-type package.

The present invention is not limited to the embodiments described above and it should be understood that the present invention may be changed and modified in various ways by those skilled in the art within a range equivalent to the spirit of the present invention and claims to be described below.

### DESCRIPTION OF MAIN REFERENCE NUMERALS OF DRAWINGS

100: Stem base

110: Glass for sealing electrode pin

120: Electrode pin

121: Electrode pin for high-speed signal transmission in single ended drive type

122, 123: Electrode pin for high-speed signal transmission in differential ended drive type

124: Electrode pin for grounding case

200: Optical element

210: Laser diode chip

220: Photodiode chip

300: Sub-mount for relaying transmitted signal

400: Metal structure having hole

410: Metal structure having one hole

420: Metal structure having two holes

700: Resistance for impedance matching

800: Thermoelectric element

820: Thermistor

900: Signal transmission line (Au wire)

1000: FPCB having ground-signal-ground (GSG) structure

1010: Signal transmission line in FPCB having ground-signal-ground (GSG) structure

1020: Ground line in FPCB having ground-signal-ground (GSG) structure

1100: FPCB including two signal transmission lines

1110: + signal transmission line in FPCB including two signal transmission lines

1120: − signal transmission line in FPCB including two signal transmission lines

1. A TO-type optical element package for high-speed communication, wherein an electrode pin (120) is inserted and fixed in a hole formed in a stem base (100) and a side of the electrode pin (120) protruding upward from the stem base (100) is surrounded by a metal structure (400) having a hole so that an impedance of the portion of the electrode pin (120) surrounded by the stem base (100) and an impedance of the portion of the electrode pin (120) protruding upward from the stem base (100) are matched.

2. The TO-type optical element package of claim 1, wherein a sub-mount (300) for relaying transmitted signals is attached to the metal structure (400) to relay signals transmitted between the electrode pin (120) and the optical element (200).

3. The TO-type optical package of claim 2, wherein the sub-mount (300) for relaying transmitted signals includes a resistance (900) for impedance matching.

4. The TO-type optical package of claim 1, wherein the sub-mount (300) for relaying transmitted signals between the electrode pin (120) and the optical element (200) is attached to the upper portion of a thermoelectric element (800) disposed on the stem base (100), and
a resistance (700) for impedance matching is attached to the metal structure (400) and connected to the sub-mount (300) for relaying transmitted signals through a signal transmission line (900).

5. The TO-type optical element package of claim 1, wherein the metal structure (400) is attached and electrically connected to the stem base (100) through a solder or conductive epoxy.

6. The TO-type optical element package of claim 1, wherein an insulating material is applied to the surface of the hole of the metal structure (400).

7. The TO-type optical element package of claim 6, wherein the metal structure (400) is made of aluminum and the surface of the hole is insulated by oxidizing the metal structure (400) made of aluminum.

8. The TO-type optical element package of claim 6, wherein an insulating layer is removed at the surface of the metal structure (400) of a portion where the metal structure (400) and the stem base (100) are in contact with each other.

9. The TO-type optical element package of claim 1, wherein when one electric line for high-speed communication is used, two ground pins (124) bonded to the TO base (100) are further attached to both sides of an electrode pin for high-speed communication.

10. The TO-type optical element package of claim 1, wherein two electric lines for high-speed communication are used, two ground pins (124) bonded to the TO base (100) are further attached to both sides of an electrode pin for high-speed communication of one metal structure (410) having two holes.

11. A TO-type optical element package for high-speed communication, wherein eight or more electrode pins including an electrode pin for high-speed transmission are included in a TO-type stem base, in which three or four electrode pins (120) are sealed by one glass sealing member (110), and an electrode pin (124) for grounding, an electrode pin (121) for high-speed signal transmission, an electrode pin (124) for grounding, and one or two common electrode pins (120) are arranged in a line opposite to the three or four electrode pins (120) sealed by one glass sealing member (110).

12. A TO-type optical element package for high-speed communication, wherein eight or more electrode pins including an electrode pin for high-speed transmission are included, in which three or four electrode pins (120) are sealed by one glass sealing member (110), three electrode pins (122, 123, 120) respectively sealed by one glass sealing member (110) are disposed opposite to the three or four electrode pins and an electrode pin (124) for grounding is disposed at a side of the stem base (100).

13. The TO-type optical element package of claim 7, wherein an insulating layer is removed at the surface of the metal structure (400) of a portion where the metal structure (400) and the stem base (100) are in contact with each other.
